(19) United States
(12) Patent Application Publication
(10) Pub. No.: US 2026/0253832 A1
(43) Pub. Date: Aug. 27, 2026

(54) POLARIZED LIGHT BRIGHT FIELD IMAGING IN CHARGED PARTICLE BEAM SYSTEMS

(71) Applicant: FEI Company, Hillsboro, OR (US)

(72) Inventors: Pavel Škarvada, Brno (CZ); Jindrich Vondruška, Brno (CZ); Adam Závodný, Brno (CZ); Pavel Friš, Brno (CZ)

(21) Appl. No.: 19/060,621

(22) Filed: Feb. 21, 2025

(51) Int. Cl. H01J 37/10; H01J 37/21; H01J 37/28; H01J 37/30

(52) U.S. Cl. CPC H01J 37/10; H01J 37/21; H01J 37/3007; H01J 37/28

(57) ABSTRACT

Charged particle beam systems, components, and methods for bright field surface profiling in charged particle beam systems are described. An optical assembly can include an illumination source, a polarization beam splitter (PBS), a collimator, a reflector, and a detector. The PBS can be oriented to receive radiation from the illumination source at a first surface and can be configured to polarize the radiation at a first polarization state and to redirect the radiation. The reflector can be configured to modify the polarization state of the radiation to a second polarization state and to redirect the radiation toward the collimator. The collimator can be oriented to receive the radiation from the PBS. The reflector can be oriented to receive the radiation from the collimator. The detector can be oriented to receive a portion of the radiation in the second polarization state from the collimator.

### TECHNICAL FIELD

Embodiments of the present disclosure are directed to charged particle beam systems, as well as algorithms and methods for their operation. In particular, some embodiments are directed toward techniques for surface reconstruction using bright field imaging.

### BACKGROUND

Positioning samples for electron microscopy can be time-intensive and requires operator diligence. Variably-sized samples on a sample holder must be carefully positioned to avoid contact with microscope components such as pole pieces used by magnetic lenses, electron detectors, or other components. In some cases, a sample holder retains multiple samples of differing heights and an operator must move each sample carefully into the microscope field of view. After positioning in the field of view, additional operator time is then required to focus the sample. Sample positioning and focusing thus are both time consuming and prone to error, and the operator skill needed can require supervision of new users who can cause sample/pole piece contact, introducing astigmatism, misalignment, or component or sample damage. For at least these reasons, improved techniques are needed for sample mapping, localization, and/or positioning.

### SUMMARY

Systems, devices, methods, algorithms, and techniques for bright field surface profiling in charged particle beam systems are described.

In a first aspect, an optical assembly includes an illumination source. The optical assembly can include a polarization beam splitter (PBS). The optical assembly can include a collimator. The collimator can be oriented to receive the radiation from the PBS. The optical assembly can include a reflector. The reflector can be oriented to receive the radiation from the collimator. The optical assembly can also include a detector. The detector can be oriented to receive a portion of the radiation in the second polarization state from the collimator. The PBS can be oriented to receive radiation from the illumination source at a first surface and can be configured to polarize the radiation at a first polarization state and to redirect the radiation. The reflector can include a waveplate. The reflector can be configured to modify the polarization state of the radiation to a second polarization state and to redirect the radiation toward the collimator.

In some embodiments, the reflector is disposed in a chamber. The collimator, the illumination source, the PBS, and the detector can be disposed external to the chamber. The sample holder can be disposed in the chamber. The holder can be configured to rotate a sample about a sample position. The sample position can be defined between the collimator and the reflector.

In some embodiments, the detector is oriented to receive the portion of the radiation via the PBS. The optical assembly can define a first optical path between the illumination source and the reflector and a second optical path between the reflector and the detector. The first optical path can define a source distance and the second optical path can define a partial focal distance. The source distance can be about equal to or greater than the partial focal distance.

The collimator can be configured to transform the radiation from a diverging wavefront between the collimator and the PBS to a substantially uniform wavefront between the collimator and the reflector. The collimator can include an aspherical lens. The waveplate can include a birefringent material.

In some embodiments, the PBS defines an internal reflective surface configured to reflect polarized radiation in the first polarization state and to transmit polarized radiation in the second polarization state. The first polarization state and the second polarization state can be linear polarization states, corresponding to respective polarization angles.

In a second aspect, a charged particle beam system includes a source of charged particles, configured to direct a beam of charged particles along an axis, a chamber, coupled with the source of charged particles, an illumination source, disposed external to the chamber and configured to generate radiation, a reflector, disposed in the chamber and defining an optical path with the source, a sample stage, disposed at least partially within the chamber and configured to retain a sample at an intersection of the axis and the optical path, and a polarization beam splitter (PBS), disposed external to the chamber. The system can include a feedthrough, coupled with the chamber. The PBS can be oriented to receive the radiation at a first surface and can be configured to polarize the radiation at a first polarization state and to redirect the radiation toward the feedthrough. The system can include a detector. The detector can be disposed external to the chamber and can be optically coupled with the reflector via the feedthrough.

In some embodiments, the beam path defines a first optical path between the illumination source and the reflector and a second optical path between the reflector and the detector. A first distance from the source to the feedthrough differs from a second distance from the feedthrough to an aperture disposed on the second segment. The aperture can be disposed substantially at a focal point of the second optical path. The reflector can include a waveplate configured to polarize the radiation to a second polarization state. The PBS can define an internal reflective surface configured to reflect polarized radiation in the first polarization state and to transmit polarized radiation in the second polarization state.

In some embodiments, systems of the second aspect can include elements of the optical assembly of the first aspect in one or more embodiments.

In a third aspect, a method of illuminating a sample includes directing radiation from an illumination source toward a first surface of a polarization beam splitter (PBS). The method can include polarizing the radiation to a first polarization state. The method can include transferring the radiation into a chamber via a collimating optic toward a reflector. The reflector can be disposed in the chamber. The reflector can include a waveplate configured to change a polarization of the radiation to a second polarization state different from the first polarization state. The method can include reflecting the radiation on the reflector via the waveplate toward the collimating optic. The method can include receiving a portion of the radiation polarized at the second polarization state at a detector. The method can also include generating bright field image data using a detector oriented to receive the portion of the radiation via the PBS.

In some embodiments, a first optical path between the illumination source and the reflector defines a source distance. A second optical path between the reflector and the detector can define a partial focal distance. The source distance can be about equal to or greater than the partial focal distance. The method can further include rotating a sample disposed in the chamber between the reflector and the collimating optic. Generating the image data can include generating a plurality of bright field images of the sample and a plurality of rotation angles.

In some embodiments, the method further includes generating profile data describing a surface of a sample using the bright field image data, the sample being disposed in the chamber and coupled with a sample stage. The method can further include generating imaging instructions to image at least a portion of the surface of the sample based at least in part on the profile data. The imaging instructions can include motion instructions describing a motion of the sample stage.

In some embodiments, the method of the third aspect can be performed using the optical assembly of the first aspect, in one or more embodiments. The method of the third aspect can be performed using the system of the second aspect, in one or more embodiments.

Embodiments of the present disclosure also include systems, components, and methods in accordance with the preceding aspects. The terms and expressions which have been employed are used as terms of description and not of limitation, and there is no intention in the use of such terms and expressions of excluding any equivalents of the features shown and described or portions thereof, but it is recognized that various modifications are possible within the scope of the claimed subject matter. Thus, it should be understood that although the present claimed subject matter has been specifically disclosed by embodiments and optional features, modification and variation of the concepts herein disclosed can be resorted to by those skilled in the art, and that such modifications and variations are considered to be within the scope of this disclosure as defined by the appended claims.

### DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram illustrating an example charged particle beam system, in accordance with some embodiments of the present disclosure.

FIG. 2 is a schematic diagram illustrating principles of operation of an example optical assembly, in accordance with some embodiments of the present disclosure.

FIG. 3 is a schematic diagram illustrating an example process for surface profiling and reconstruction, in accordance with some embodiments of the present disclosure.

FIG. 4 is a schematic diagram illustrating an example optical assembly mounted to a component of a charged particle beam system, in accordance with some embodiments of the present disclosure.

FIG. 5 is a schematic diagram illustrating a component of an optical assembly including a polarization beam splitter, in accordance with some embodiments of the present disclosure.

FIG. 6 is a schematic diagram illustrating an example optical assembly configured without a beam splitter.

FIG. 7 is a block flow diagram describing an example process for generating map data describing a sample, in accordance with some embodiments of the present disclosure.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While embodiments have been illustrated and described, it will be appreciated that various changes can be made therein without departing from the spirit and scope of the disclosure. In the forthcoming paragraphs, embodiments of a charged particle beam system, components, and methods for bright field surface profiling in charged particle beam systems are described. Embodiments of the present disclosure focus on sample microanalysis using scanning electron microscope (SEM) systems in the interest of simplicity of description. Embodiments are not limited to such systems, but rather are contemplated for systems configured for analysis of surface topology. In an illustrative example, x-ray photoelectron spectroscopy (XPS) systems can employ techniques of the present disclosure as part of mapping studies of material samples. Similarly, ion beam systems can be configured to perform at least some techniques of the present disclosure, such as broad ion beam systems, focused ion beam systems, or the like. As such, while embodiments of the present disclosure focus on SEM platforms equipped with systems for generating and processing polarized light image data, additional and/or alternative systems and approaches are contemplated.

Embodiments of the present disclosure include systems, methods, algorithms, and non-transitory media storing computer-readable instructions for mapping a sample surface in a charged particle beam system. In an illustrative example, a charged particle beam system can include directing radiation toward a first surface of a polarization beam splitter (PBS), polarizing the radiation to a first polarization state, transferring the radiation into a chamber via a collimating optic toward a reflector, disposed in the chamber, the reflector comprising a waveplate configured to change a polarization of the radiation to a second polarization state different from the first polarization state, reflecting the radiation on the reflector via the waveplate toward the collimating optic, receiving a portion of the radiation polarized at the second polarization state at a detector, and generating bright field image data using a detector oriented to receive the portion of the radiation via the PBS. Advantageously, embodiments of the present disclosure improve techniques for mapping samples in situ, at least in part by attenuating reflection artefacts in bright-field image data, by reducing physical constraints on components of the optical system, and by reducing thermal loading within a sample chamber of the charged particle beam systems, thereby reducing detector crosstalk for those sensors that are susceptible to interference from visible and/or infrared radiation sources.

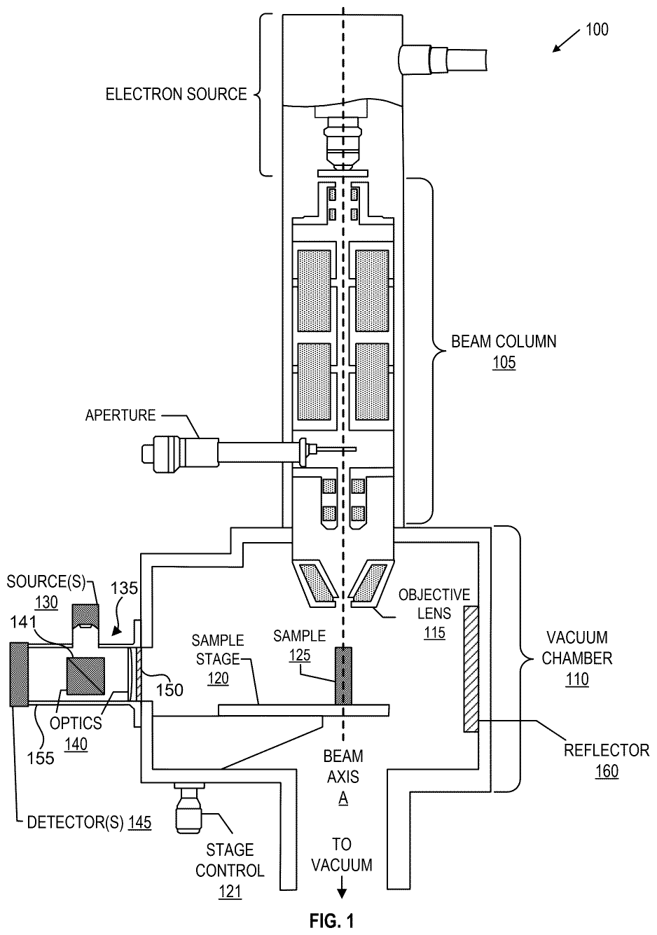

FIG. 1 is a schematic diagram illustrating an example charged particle beam system 100, in accordance with some embodiments of the present disclosure. Example system 100 includes multiple sections including an electron source, a beam column 105, and a vacuum chamber 110. The electron source includes high-voltage supply components, vacuum system components, and an electron emitter configured to generate a beam of electrons that is accelerated into the beam column 105. The beam column 105, in turn, includes electromagnetic optical elements that are configured to shape and form the beam of electrons from the electron source in accordance with a given beam shape and a profile transverse to a beam axis A, and conditions the beam to be focused onto a sample 125 and/or transmitted through the sample 125 using an objective lens 115.

The beam of electrons can be characterized by a beam current and an accelerating voltage applied to generate the beam, among other criteria. The ranges of beam current and accelerating voltage can vary between instruments and are typically selected based on material properties of the sample or the type of analysis being conducted. Generally, however, in a scanning electron microscope, beams of electrons are characterized by an energy from about 0.01 keV (e.g., for an accelerating voltage of 0.1 kV) to about 50 keV and a beam current from picoamperes to microamperes.

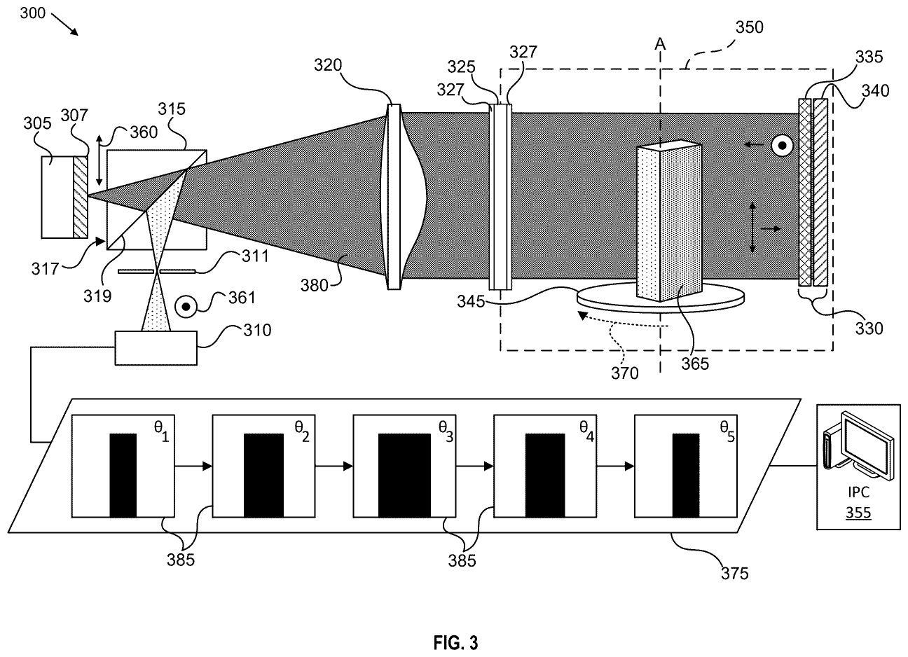

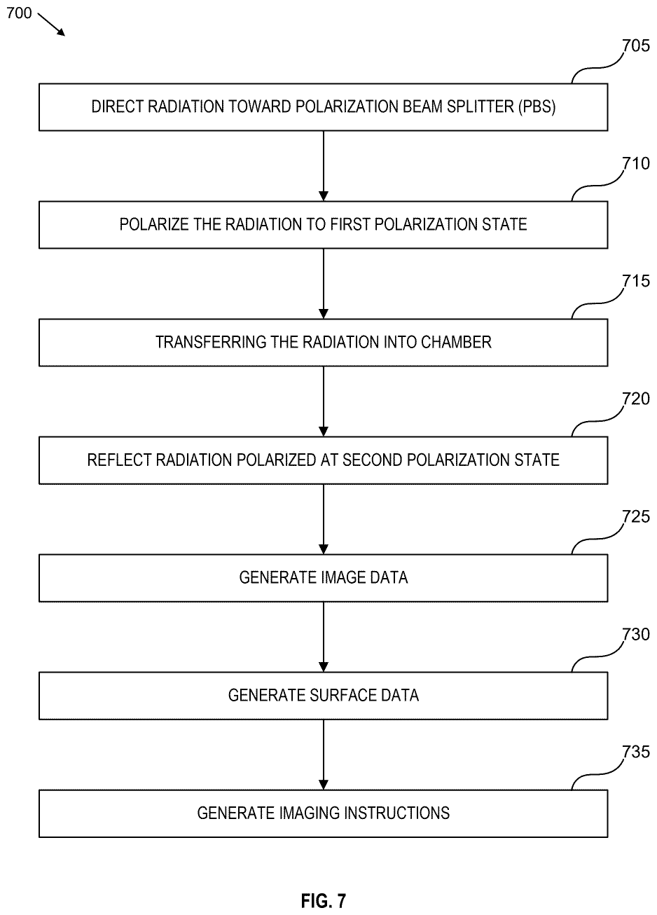

The vacuum chamber 110 and/or the beam column 105 can include multiple detectors for various signals, including but not limited to secondary electrons generated by interaction of the beam of electrons and the sample, x-ray photons (e.g., EDAX), other photons (e.g., visible and/or IR cameras), and/or molecular species (e.g., TOF-SIMS), not shown in FIG. 1 in the interest of focusing description on optical elements of the present disclosure. The vacuum chamber 110 can also include a sample stage 120 that can be operably coupled with a multi-axis translation/rotation control system 121, such that the sample 125 can be repositioned relative to the beam axis A, as an approach to surveying and/or imaging the sample 125. As described in more detail in reference to FIG. 3, the control system 121 can coordinate the operation of the sample stage 120 as part of a process for mapping, localizing, and/or positioning the sample 125, for example, as part of a surface profiling technique, an example of which is described in reference to FIG. 7.

Example system 100 is illustrated as a single-beam SEM instrument to focus description on applications of charged particle beam systems. In some embodiments, example system 100 can incorporate an ion-beam source (e.g., a focused ion beam, or FIB as part of a dual-beam system) adapted, for example, to modify a sample or for microanalysis. Charged particle sensors of the present disclosure can be configured to generate detector data (e.g., images, line scans, x-ray spectra, etc.) in coordination with ion-sources used for modification and/or microanalysis of samples. In an illustrative example, a focused ion source (e.g., a p-FIB, Ga-FIB, or the like) can be operably coupled with the vacuum chamber 110 and configured to incrementally remove portions of the sample 125 in a layer-wise manner and/or for sectioning the sample 125. Between increments, x-ray microanalysis of the sample 125 affords a depth profile of elemental information in the sample 125, which can be useful for quality assurance in semiconductor applications, as well as in other fields.

Similarly the example system 100 can include a source of radiation 130, such as a monochromatic photon source (e.g., a laser, LED or LED panel, etc.) and/or a polychromatic photon source (e.g., a tungsten halogen source, UV-Visible source, etc.) or other electromagnetic radiation source. Advantageously, the radiation source 130 can be disposed external to the vacuum chamber 110, for example, in an optical assembly 135 that is coupled with the vacuum chamber 110. In some embodiments, the source of radiation 130 is disposed in the vacuum chamber 110, for example, as part of a multi-purpose illumination system that is also used to guide a user of the system 100 during sample loading/unloading and for visualizing the interior of the chamber 110.

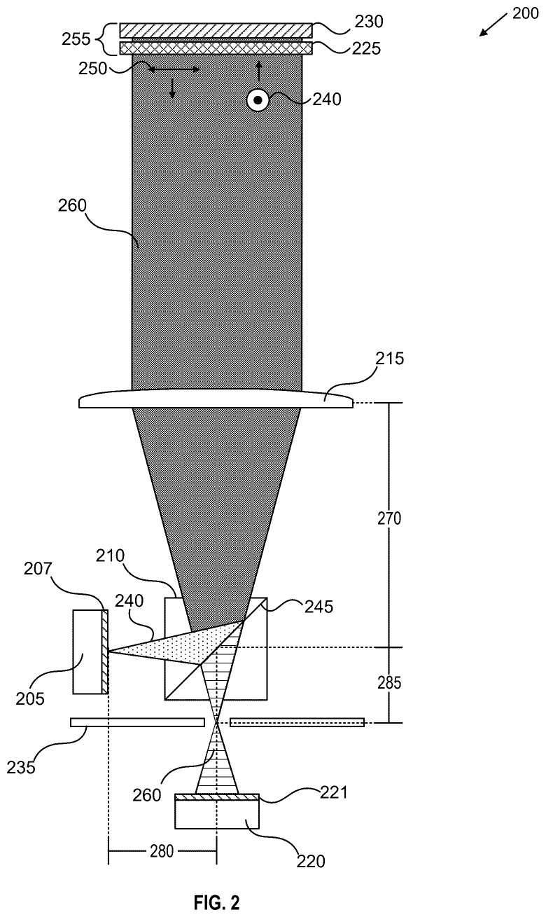

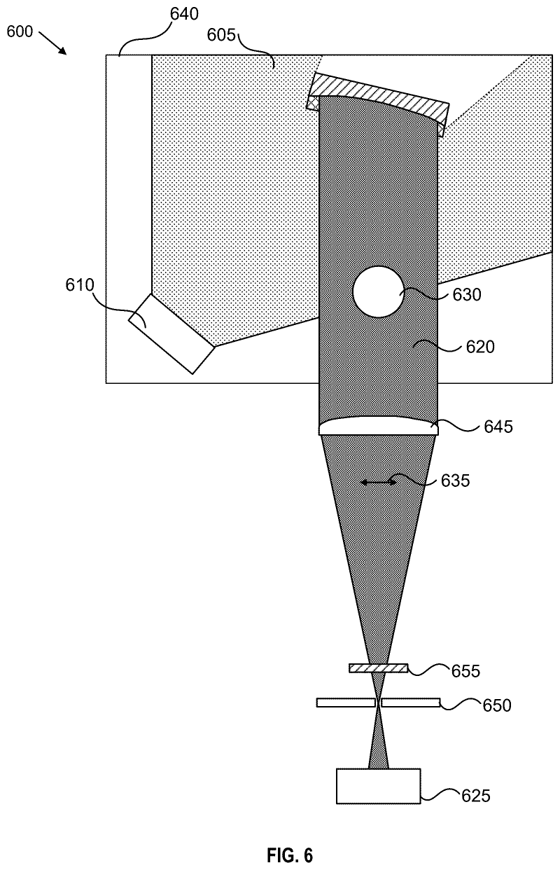

The assembly 135 can include one or more optics 140, and one or more detectors 145. The optic(s) 140 can include optical elements configured to apply a first polarization state to the radiation emitted by the source(s) 130. For example, the optic(s) 140 can include a polarization beam splitter 141 configured to polarize incident radiation at the first polarization state and to reflect the polarized radiation toward the vacuum chamber 110. As described in more detail in reference to FIGS. 2-3, the beam splitter 141 can include an internal reflective surface having a polarization-dependent reflectance. In this way, the polarization beam splitter 141 can transmit radiation that is polarized at a second polarization state that is different from the first polarization state. In some embodiments, the assembly 135 can include multiple optics 140 that together perform the functions of a polarization beam splitter, for example, by including a polarization-selective mirror and a polarizer. Alternatively, the assembly can define multiple optical paths such that the polarization selective mirror is omitted, as described in reference to FIG. 6.

The optics 140 can further include one or more lenses, as described in more detail in reference to FIGS. 2-3. The lens(es) can be configured to act as a collimator. In this way, the lens(es) can be configured to transform the radiation emitted from the source(s) 130 such that the radiation defines a substantially uniform wavefront in the vacuum chamber 110. Advantageously, propagating a substantially uniform light field into the vacuum chamber improves the quality of bright-field images of the sample 125, where the background of the image is relatively bright and the sample is relatively dark, by improving the uniformity of the background.

The assembly 135 can be coupled with the vacuum chamber via an optical feedthrough 150, permitting the internal volume of the assembly 135 to be maintained at ambient conditions and to remain accessible while the vacuum chamber 110 is evacuated. The optical feedthrough 150 can be or include a material that is substantially transparent to radiation having energ(y) (ies) and polarization state(s) that are emitted by the source(s) 130. For example, the optical feedthrough 150 can be or include a window including a material that is substantially transparent to UV-visible photons, x-ray photons, or the like, and that can be provided with an anti-reflective coating on one or more faces. In some embodiments, the window can be substantially opaque to photons having an energy above a given threshold, as an approach to shielding the optics from radiation that can be generated by interactions of the sample and the beam of charged particles. For example, the window can be substantially opaque or have a limited transparency to x-rays, or can otherwise serve to reduce the transmission of x-rays through the window.

Alternatively, the assembly 135 can be coupled with the vacuum chamber via a vacuum-tight flange (e.g., a KF-type flange, a CF-type flange, etc.), thereby omitting the feedthrough 150, such that at least part of the internal volume of the assembly 135 to be evacuated to substantially the same pressure as the vacuum chamber 110. In an example, as illustrated in FIG. 5, one or more optics 140 can be disposed in a vacuum-compatible housing 155 defining one or more flanged ends (referred to in FIG. 5 as flanged ends 515), at which the assembly 135 can be coupled with the vacuum chamber 110. In some embodiments, the source(s) 130 and/or the detector(s) 145 are coupled with a vacuum-compatible element defining a complementary flanged end, as via an optical and/or electrical feedthrough, by which the source(s) 130 and/or the detector(s) 145 can communicate optically with the optic(s) 140 of the assembly 135.

In some embodiments, the optical assembly 135 includes a reflector 160, disposed in the vacuum chamber 110. The assembly 135 and the reflector 160 can be oriented such that an optical path from the assembly 135 to the reflector 160 crosses the beam axis A substantially at a position of the sample 125, as described in reference to FIGS. 2-3. The reflector 160 can be or include a composite of a reflective material (e.g., a metallic mirror, a distributed Bragg reflector, etc.) and a waveplate, as described in more detail in reference to FIGS. 2-3 that together reflect incident radiation and polarize the radiation from the first polarization state to the second polarization state. In this way, radiation that is reflected by the sample 125, being polarized at the first polarization state, is filtered by the optic(s) 140 and does not reach the detector(s) 145. In contrast, radiation that is reflected by the reflector 160, being polarized at the second polarization state, is transmitted by the optic(s) 140 and reaches the detector(s) 145. Advantageously, repolarization of incident radiation at the reflector 160 improves the quality of bright-field images by darkening the sample 125 in the images and sharpening the profile of the sample 125, relative to the bright background field, and further improves techniques for surface profilometry, sample localization, and surface mapping.

FIG. 2 is a schematic diagram illustrating principles of operation of an example optical assembly 200, in accordance with some embodiments of the present disclosure. The assembly 200 is an example of the assembly 135 of FIG. 1, including a radiation source 205, a polarization beam splitter 210 (referred to as PBS 210), a collimator 215, a detector 220, a reflector 255 that includes a waveplate 225 and a reflective element 230, and an aperture 235. Elements of the example system 100 of FIG. 1, including the components of the charged particle beam system (e.g., beam column 105, vacuum chamber 110, sample stage 120, sample holder 125, etc.) are omitted from FIG. 2 to focus discussion on the optical aspects of the assembly 200.

The radiation source 205 and the detector 220 can be coordinated such that the radiation emitted by the source 205 can have an average energy to which the detector 220 is sensitive. For example, the radiation source 205 can include a laser and/or a monochromatic light emitting diode configured to emit photons in the visible spectral range. An advantage of a monochromatic photon source in the context of the present disclosure is the substantial reduction or elimination of chromatic aberration, relative to a polychromatic source. Corresponding to this, the detector 220 can include a charge-coupled device (CCD) that is configured to detect visible photons including photons at the average energy and generate signals that can be processed into image data (e.g., using a pixelated detector). The radiation source 205 can include a first polarizing filter 207 that applies a first polarization state 240 to the radiation. Alternatively, the first polarizing filter 207 can be disposed as a coating on the PBS 210 or as an optical element disposed along an optical path between the source 205 and the PBS 210.

The PBS 210 can include a substantially transparent material that defines an internal reflective surface 245. The internal reflective surface 245 can include a material that is reflective of the radiation emitted from the source. The internal reflective surface 245 can be formed in such a way that radiation that is polarized at the first polarization state 240 is reflected toward the collimating lens 215, and radiation that is polarized at a second polarization state 250 is transmitted through the internal reflective surface 245 toward the detector 220, if originating from the reflector 255, and through the PBS 210 and away from the detector 220 if originating from the source 205 (e.g., in an unpolarized source). A second polarizing filter 221 can be coupled with the detector 220 (e.g., disposed as a coating 210, mechanically coupled with a housing of the detector, etc.), or can be provided as an optical element disposed along an optical path between the PBS 210 and the detector 220. Advantageously, including the second polarizing filter can improve data generated by the detector, for example, by attenuating noise attributable to reflected radiation, external sources, or the like that would otherwise reach the detector.

The source 205 can be configured to emit radiation in a diverging wavefront, as shown in FIGS. 2-3. As such, the collimator 215 can define a lens profile such that radiation is condensed into a substantially uniform beam profile along an optical path 260 between the collimator 215 and the components of the reflector 255 (e.g., the waveplate 225 and the reflective element 230). The components of the example assembly 200 can be oriented such that the optical path 255 can cross a beam axis of an analytical instrument (e.g., beam axis A of FIG. 1) over an area that includes a sample position. In this way, the image data generated using the detector 220 can be used to guide the analysis and/or processing of a sample (e.g., sample 125 of FIG. 1) by a different analysis technique (e.g., charged particle beam microscopy and microanalysis, x-ray microanalysis, charged particle processing, etc.), as described in more detail in reference to FIG. 3 and FIG. 6.

In some embodiments, the example assembly 200 defines a first optical path 260 between the illumination source 205 and the reflector 255 and a second optical path 265 between the reflector 255 and the detector 220. The first optical path 260 and the second optical path 265 can be coincident over at least a portion of their respective paths. The first optical path 260 and the second optical path 265 can intersect the reflective surface 245 of the PBS 210 at substantially the same point (as shown in FIG. 2) or at different points on the reflective surface 245, with accompanying modifications to the optical paths relative to what is illustrated in FIG. 2. In some embodiments, a first path length of the first optical path 260 includes a common distance 270 between the collimating lens 215 and the reflective surface 245, and a source distance 280 between the reflective surface 245 and the source 205. Similarly, a second path length of the second optical path 265 can include the common distance 270 and a partial focal distance 285 between the reflective surface 245 and a focal point coinciding with the aperture 235.

The source distance 280 and the partial focal distance 285 can be substantially the same, or different. Advantageously, configuring the example assembly 200 such that the source distance 275 differs from the focal distance 280 can improve the quality of bright field image data, relative to configurations in which the source distance 280 and the partial focal distance 285 are substantially equal. For example, configuring the source 205 such that the source distance 280 is larger than the partial focal distance 280 can attenuate the appearance of artefacts in bright-field image data that are attributable to the shadow of the sample on the reflector being larger than the actual size of the object. As a result, this degrades the edges in the detected image. This technique is also referred to as “near telecentric” imaging. In addition, the selective detection of radiation in the second polarization state reduces the appearance of reflections from the environment of the sample, referred to as parasitic reflections, which would otherwise obscure and/or alter the silhouette of the sample against the bright field of the image.

FIG. 3 is a schematic diagram illustrating an example process 300 for surface profiling and reconstruction, in accordance with some embodiments of the present disclosure. The components of the systems shown in FIG. 3 are examples of the elements described in reference to FIGS. 1-2. For example, the optical elements whose operation is described are examples of the optical components described in FIG. 2 and the chamber and sample control and motion elements are examples of the stage and stage control elements described in reference to FIG. 1 that can be operated in the manner described below, as part of a data processing workflow for imaging, profiling, localizing, and/or repositioning a sample during imaging, processing, or microanalysis in a charged particle beam system. To that end, FIG. 3 describes constituent operations of a process that includes iteratively rotating and/or translating a sample, generating detector data, and transferring data between components of the system. Additional and/or alternative operations are described in more detail in reference to FIG. 6.

The example process 300 can be performed by elements of an optical assembly (e.g., optical assembly 200 of FIG. 2, assembly 135 of FIG. 1, etc.) including a source 305, a detector 310, a PBS 315, a collimator 320, an optical feedthrough 325, a reflector 330 including a waveplate 335 and a reflective element 340, as well as elements of an analytical instrument system (e.g., the system 100 of FIG. 1), such as a sample holder 345, a vacuum chamber 350, and an instrument computing device (IPC) 355. In the configuration illustrated in FIG. 3, some components are disposed in the vacuum chamber 350 and some components are external to the vacuum chamber 350. For example, the sample holder 345 can be disposed in the chamber 350. The source 305 is provided with a polarizing filter 307, configured to polarize radiation to a first polarization state 360, which is shown as a linear polarization state associated with a polarization angle. The polarizing filter 307, the PBS 315, and the waveplate 335, etc., can be configured for additional or alternative polarization states, of which elliptical polarization is an example (e.g., circular polarization in left and right directional states). Elements of the assembly 300 can be replaced with functional analogues that are configured for elliptical polarization. For example, a combination of optics can be arranged to reproduce the function of the PBS 315 to reflect or transmit and filter the radiation leaving the source 305.

The sample holder 345 can be configured to rotate 370 a sample 365 about a sample position. In some embodiments, the sample position is defined between the optical feedthrough 325 and the reflector 330. As described in more detail in reference to FIG. 2, the optical components of the assembly can be oriented relative to each other, such that radiation emitted by the source 305 can be directed into the chamber 350, through the chamber 350 to the reflector 330, crossing the sample position and being at least partly absorbed and/or reflected by the sample 365. To that end, the optical feedthrough 325 can be provided with one or more coatings 327 to improve the optical performance, mechanical strength, or other property of the feedthrough 325 (e.g., an anti-reflective coating, or the like).

In the example of visible photons, a sample that is opaque to a monochromatic photon source (e.g., a monochromatic LED panel or a laser source) can produce a relatively dark silhouette against a bright field. A dark silhouette, measured repeatedly over multiple rotations 370, can be used to generate surface information describing the shape, topography, and location of at least part of the sample 365.

In some embodiments, the source 305, the PBS 315, the aperture 311, and the detector 310 are external to the vacuum chamber, as described in more detail in reference to FIGS. 1-2. To that end, the optical elements can be mechanically coupled with adjustable holders, housings, fittings, retaining members, or the like, such that the optical elements can be aligned with respect to each other and/or the sample 365. In an illustrative example, the reflector 330 can be adjustably coupled with an inner wall of the vacuum chamber 350 using a motion damping linkage that reduces aberrations in image data 375 (e.g., motion arising from vibration in the analytical instrument). The detector 310 can be operably coupled with the IPC 355 via one or more electronic couplings. For example, the detector 310 can be coupled with the IPC 355 via data and power connections (e.g., a wired bus connection) that can be wired and/or wireless. In some embodiments, the detector 310 and the IPC 355 are coupled via intermediate electronic circuitry, such as may be configured to coordinate the operation of the various components of the analytical instrument with the IPC 355.

The collimator 320 can include one or more constituent elements, such as lenses, apertures, collimator tubes, irises, filters, or the like. In some embodiments, the collimator 320 includes an aspherical lens, defining a lens profile that receives a divergent beam and transmits a substantially parallel beam. Advantageously, using an aspherical lens can form a beam that is characterized by negligible or no spherical aberration, thereby improving the quality of the image data 375 and resultant sample profile information. The collimator 320 can include multiple lenses, a compound lens, Fresnel lens(es), or the like, as part of configuring the collimator 320 to condense the divergent radiation into a substantially parallel beam.

The example process 300 includes directing radiation 380 toward a first surface 317 of the PBS 315 (e.g., using the LED). The process 300 includes polarizing the radiation 380 to the first polarization state 360, shown as a linear polarization state aligned with a first polarization angle. The example process 300 includes transferring the radiation 380 into a chamber via the collimator 320 toward the reflective element 340. In the system of elements illustrated in FIG. 3, the reflector 330 includes a waveplate 335 configured to change the polarization of back-reflected radiation 380 from the first polarization state to a second polarization state 361 different from the first polarization state. In the case of a linear polarizer system, the first polarization state 360 and the second polarization state 361 are both linear polarization states, corresponding to respective polarization angles. Among the approaches for modifying the polarization state of the radiation 380, the waveplate 335 can include a birefringent material (e.g., calcite, quarts, birefringent polymers, potassium dihydrogen phosphate, etc.), thin film coatings, wire-grid polarizers, glass polarizers, or the like.

The process 300 includes reflecting the radiation 380 on the reflective element via the waveplate 335 toward the collimator 320. In this way, the back-reflected radiation 380 is polarized at the second polarization state 361, which can be transmitted back through the collimator 320, to the PBS 315, and reflecting the radiation in the second polarization state 361 on the internal reflective surface of the PBS 319, toward to the detector 310. In contrast to the example system 200 of FIG. 2, the PBS 315 is oriented to reflect the radiation 380 in the second polarization state 361, rather than the radiation 380 in the first polarization state 360.

The process further includes receiving at least a portion of the radiation polarized at the second polarization state 361 at the detector 310 (e.g., considering non-zero absorption by the various optics along the beam path). The detector 310 can generate the bright field image data 375 in response to receiving the portion of the radiation 380 via the PBS 15, based at least in part on the interaction of the radiation 380 with radiation sensitive components of the detector (e.g., a pixelated CCD or other imaging sensor).

The example process 300 includes rotating the sample 365, such that such that generating the image data 375 can include generating a plurality of bright field images 385 of the sample 365 in silhouette and a plurality of rotation angles, indicated in FIG. 3 with enumerated θ values. In this way, the image data 375 can include multiple images 385 that can correspond to multiple angles, from which surface information describing the sample 365 can be derived using one or more digital image processing routines. For example, routines for mapping the sample surface can include, but are not limited to, spin-image mapping, texture mapping, and surface parametrization. In reference to FIG. 3, the image data 375 can be processed using the IPC 355 and/or additional or alternative systems. In some embodiments, image data 375 are transferred to other computing systems and/or devices, such as a client computing device (e.g., a personal computer) or a compute instance hosted in a distributed computing system.

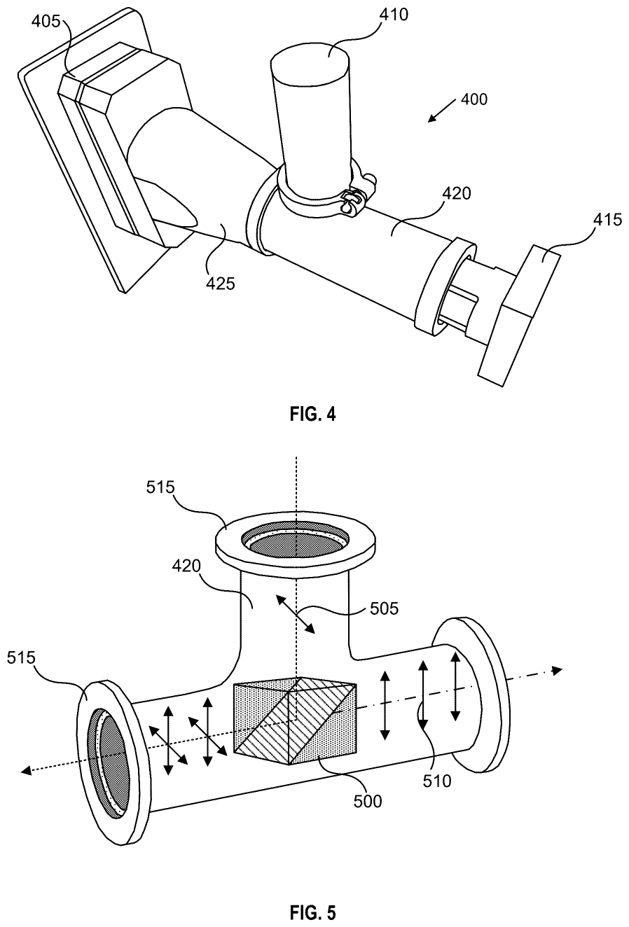

FIG. 4 is a schematic diagram illustrating an example optical assembly 400 mounted to a vacuum fitting 405 of a charged particle beam system, in accordance with some embodiments of the present disclosure. The assembly 400 is an example of the assembly 135 of FIGS. 1, 200 of FIG. 2, and is configured in accordance with performing at least a portion of the process 300 of FIG. 3. The assembly 400 includes a source 410, a detector 415, and vacuum chamber components including a vacuum tee 420 and an adapter flange 425. The illustrated components of the assembly 400 can be configured to maintain a vacuum environment around the optical components of the assembly 400, disposed within the vacuum tee 420 and/or the adapter flange 425. In some embodiments, the components of the optical assembly 400 are coupled with the vacuum chamber via a feedthrough (e.g., feedthrough 150 of FIG. 1), and, in this way, the environment of the optical elements, the source 410, and the detector 415, is not evacuated. In an example, the feedthrough can be a material that is transparent to relatively low energy photons (e.g., UV, Visible, or IR), but is opaque to relatively high energy photons (e.g., x-rays) and can be mechanically strong enough to maintain a vacuum tight seal between the assembly 400 and the vacuum fitting 405. To that end, the components of the assembly 400 can be configured to retain the optics in alignment, but without being configured to maintain a vacuum environment around the optics.

An example of the internal position of the PBS is shown in FIG. 5 (labeled with numeral 500). In the assembly of FIG. 4, elements such as wiring, threaded adjusters, or the like, are omitted for simplicity of description. The assembly 400 is shown with a combination of KF-flanged and CF-flanged components, but can include one or the other type, alone or in combination. FIG. 5 further illustrates the function of the PBS 500 to separate radiation spatially in different portions of the vacuum tee 420. For example, radiation in the first polarization state 505, emitted by the source, can be reflected by the PBS, while radiation in the second polarization state 510 can be reflected by the PBS 500 toward the detector. In FIG. 5, the vacuum tee 420 includes flanged ends 515 that are configured for KF-type connectors. The example embodiments of FIGS. 4-5 can include an optical feedthrough (e.g., optical feedthrough 325 of FIG. 3), as an approach to reducing contamination of the optics disposed in the adapter 425 and/or the tee 420, etc., which can arise from sample processing operations that involve material entering the vacuum environment (e.g., sample material removal). In some embodiments, the optical feedthrough is omitted.

FIG. 6 is a schematic diagram illustrating an example optical assembly 600 configured without a beam splitter. In contrast to the embodiments of the present disclosure that rely on a polarizing beam splitter (PBS) to filter radiation in the second polarization state from radiation in the first polarization state, as described in more detail in reference to FIGS. 1-5, the example assembly 600 omits the PBS by defining different forward and reflected beam paths. A forward beam path 605 can be defined between a source 610 and a reflector 615 via one or more optical elements. A second beam path 620 can be defined between the reflector 615 and a detector 625, such that the second beam path 620 crosses a sample position 630. The first beam path 605 can cross the sample position 630, or it can bypass the sample position 630. Advantageously, bypassing the sample position 630 can improve the quality of bright-field image data (e.g., image data 375 of FIG. 3) generated by the detector 625 at least in part by reducing reflections on the face of sample that is nearest the detector 25, in cases where the radiation along the first beam bath 605 includes a non-zero component at the second polarization state 635. For example, where the radiation emitted toward the reflector 615 is not polarized.

The source 610 and the reflector 615 of the assembly 600 are disposed within a chamber 640 of an instrument. In some embodiments, the source 610 is a multipurpose illumination source, such as a lamp that can also serve as a chamber illuminator for use during sample loading/unloading and to visualize the interior of the chamber 640. As described in more detail in reference to FIGS. 1-3, some elements of the assembly 600 can be disposed external to the chamber 340, such as optics 645 (e.g., lenses, filters, and/or apertures). The assembly 600 also includes optics, such as focusing lens(es) 645 to focus the second beam path 620 substantially at the position of an aperture 650, and a polarization filter 655, configured to selectively transmit radiation that is polarized at the second polarization state 635.

FIG. 7 is a block flow diagram describing an example process 700 for generating map data describing a sample, in accordance with some embodiments of the present disclosure. One or more operations making up the example process 700 can be executed by a computer system or other programmable logic (e.g., IPC 355 of FIG. 3), operably coupled with components of a charged particle microscope (e.g., charge particle beam system 100 of FIG. 1) and/or additional systems or subsystems including, but not limited to, characterization systems, power supply systems, network infrastructure, databases, and/or user interface devices. To that end, operations of example process 700 can be stored as machine executable instructions in one or more machine readable media.

One or more operations of the example process 700 can be repeated, reordered, and/or omitted, for example, as part of generating bright-field image data and/or imaging instructions using an optical assembly of the present disclosure. To that end, the operations of example process 700 are described as being performed by a system, where it is understood that the operations can include generating and communicating control signals between a processor or other logic circuitry and electronic or electromechanical elements of the charged particle beam system. The operations of example process 700 are described in the context of an electron microscope in the interest of clarity. The example process 700 omits one or more operations that can precede and/or follow the operations of example process 700. For example, operations can include drawing and maintaining a vacuum in a vacuum enclosure (e.g., vacuum chamber 110 of FIG. 1, vacuum chamber 350 of FIG. 3, etc.) in which a sample is disposed, imaged, and/or processed. Similarly, operations can include one or more control schemes (e.g., feedback, feedforward, etc.) by which the systems of the present disclosure can modulate one or more operating parameters of the system (e.g., by generating motion instructions to move the sample between different imaging positions).

At operation 705, example process 700 includes directing radiation toward a first surface of a polarization beam splitter (PBS). As described in more detail in reference to FIGS. 2-3, the PBS can define multiple surfaces through with radiation in different polarization states can be directed (e.g., by means of a polarizing filter formed on an internal reflective surface). To that end, the PBS can be oriented to reflect the radiation directed toward the first surface off an internal reflective surface or to transmit the radiation through the internal reflective surface.

To that end, example process 700 can include polarizing the radiation to a first polarization state at operation 710. As described in more detail in reference to FIGS. 1-4, operation 710 can include transmitting the radiation via a polarizing filter disposed along a first beam path between a radiation source and the PBS (or between the source and a reflector, in the case of example assembly 600 of FIG. 6). The polarizing filter can be an independent optical element or can be formed as a layer or other constituent component of the source, such that the source emits polarized radiation.

At operation 715, example process 700 includes transferring the radiation into a chamber via a collimating optic toward a reflector, as described in more detail in reference to FIGS. 1-6. In this way, the reflector can be disposed in the chamber. The reflector can include a waveplate configured to change a polarization of the radiation to a second polarization state, such that the PBS can filter radiation incident on the first surface from radiation that is reflected back toward the detector via the waveplate at operation 720. In some embodiments, as when the optical assembly is disposed within a vacuum environment (e.g., as illustrated in FIG. 1 and FIGS. 4-5), operation 715 is omitted.

At operation 725, example process 700 includes receiving a portion of the radiation polarized at the second polarization state at the detector, as described in more detail in reference to FIGS. 1-6. The radiation in the second polarization state can be linearly polarized, circularly polarized, or the like, and can be transmitted through the PBS or reflected on the internal reflective surface of the PBS, such that the detector can generate bright field image data.

In some embodiments, example process 700 includes generating surface data describing a sample at operation 730, at least in part by rotating the sample disposed in the chamber at a position between the reflector and the collimating optic. To that end, operation 730 can include generating multiple bright field images of the sample at multiple rotation angles, as described in more detail in reference to FIG. 3. The image data, thus generated, can be used to generate profile data, map data, and/or data describing a 3D reconstruction of the sample, with which further operations of the system can be coordinated. For example, example process 700 can include generating imaging instructions at operation 735. In this context, imagine instructions can include motion instructions describing a motion of the sample stage and/or control instructions for one or more components of a charged particle beam system (e.g., beam scan pattern, image capture instructions, etc.). In an illustrative example, the charged particle beam system can be directed to image at least a portion of the surface of the sample based at least in part on the profile data.

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on electron microscopy systems, and scanning transmission electron microscopy systems in particular, these are meant as non-limiting, illustrative embodiments. Embodiments of the present disclosure are not limited to such embodiments, but rather are intended to address analytical instruments systems for which a wide array of material samples can be analyzed to determine chemical, biological, physical, structural, or other properties, among other aspects, including but not limited to chemical structure, trace element composition, or the like. As such, embodiments of the present disclosure include charged particle instruments more broadly, including focused ion beam systems, scanning electron microscope systems, electron beam microanalysis systems, or the like.

Some embodiments of the present disclosure include a system including one or more data processors and/or logic circuits. In some embodiments, the system includes a non-transitory computer readable storage medium containing instructions which, when executed on the one or more data processors and/or logic circuits, cause the one or more data processors and/or logic circuits to perform part or all of one or more methods and/or part or all of one or more processes and workflows disclosed herein. Some embodiments of the present disclosure include a computer-program product tangibly embodied in non-transitory machine-readable storage media, including instructions configured to cause one or more data processors and/or logic circuits to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property within which the deviation has little to no influence of the corresponding function, property, or attribute of the structure being described. In an illustrated example, where a dimensional parameter is described as “substantially equal” to another dimensional parameter, the term “substantially” is intended to reflect that the two parameters being compared can be unequal within a tolerable limit, such as a fabrication tolerance or a confidence interval inherent to the operation of the system. Similarly, where a geometric parameter, such as an alignment or angular orientation, is described as “about” normal, “substantially” normal, or “substantially” parallel, the terms “about” or “substantially” are intended to reflect that the alignment or angular orientation can be different from the exact stated condition (e.g., not exactly normal) within a tolerable limit. For numerical values, such as diameters, lengths, widths, or the like, the term “about” can be understood to describe a deviation from the stated value of up to ±10%. For example, a dimension of “about 10 mm” can describe a dimension from 9 mm to 11 mm.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims. Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

What is claimed is:

1. An optical assembly, comprising:
an illumination source;
a polarization beam splitter (PBS), the PBS being oriented to receive radiation from the illumination source at a first surface and being configured to polarize the radiation at a first polarization state and to redirect the radiation;
a collimator, oriented to receive the radiation from the PBS;
a reflector, comprising a waveplate, oriented to receive the radiation from the collimator and configured to modify the polarization state of the radiation to a second polarization state and to redirect the radiation toward the collimator; and
a detector, oriented to receive a portion of the radiation in the second polarization state from the collimator.

2. The optical assembly of claim 1, wherein the reflector is disposed in a chamber, and wherein the collimator, the illumination source, the PBS, and the detector are disposed external to the chamber.

3. The optical assembly of claim 2, wherein a sample holder is disposed in the chamber, the holder being configured to rotate a sample about a sample position, the sample position being defined between the collimator and the reflector.

4. The optical assembly of claim 1, wherein the detector is oriented to receive the portion of the radiation via the PBS.

5. The optical assembly of claim 1, defining a first optical path between the illumination source and the reflector and a second optical path between the reflector and the detector, wherein:
the first optical path defines a source distance;
the second optical path defines a partial focal distance; and
the source distance is about equal to or greater than the partial focal distance.

6. The optical assembly of claim 1, wherein the collimator is configured to transform the radiation from a diverging wavefront between the collimator and the PBS to a substantially uniform wavefront between the collimator and the reflector.

7. The optical assembly of claim 6, wherein the collimator comprises an aspherical lens.

8. The optical assembly of claim 1, wherein the waveplate comprises a birefringent material.

9. The optical assembly of claim 1, wherein the PBS defines an internal reflective surface configured to reflect polarized radiation in the first polarization state and to transmit polarized radiation in the second polarization state.

10. The optical assembly of claim 9, wherein the first polarization state and the second polarization state are linear polarization states, corresponding to respective polarization angles.

11. A charged particle beam system, comprising:
a source of charged particles, configured to direct a beam of charged particles along an axis;
a chamber, coupled with the source of charged particles;
an illumination source, disposed external to the chamber, configured to generate radiation;
a feedthrough, coupled with the chamber;
a reflector, disposed in the chamber and defining an optical path with the source;
a sample stage, disposed at least partially within the chamber and configured to retain a sample at an intersection of the axis and the optical path;
a polarization beam splitter (PBS), disposed external to the chamber, the PBS being oriented to receive the radiation at a first surface and configured to polarize the radiation at a first polarization state and to redirect the radiation toward the feedthrough; and
a detector, disposed external to the chamber and optically coupled with the reflector via the feedthrough.

12. The system of claim 11, wherein the beam path defines a first optical path between the illumination source and the reflector, and a second optical path between the reflector and the detector, wherein a first distance from the source to the feedthrough differs from a second distance from the feedthrough to an aperture disposed on the second segment, and wherein the aperture is disposed substantially at a focal point of the second optical path.

13. The system of claim 11, wherein the reflector comprises a waveplate configured to polarize the radiation to a second polarization state.

14. The system of claim 13, wherein the PBS defines an internal reflective surface configured to reflect polarized radiation in the first polarization state and to transmit polarized radiation in the second polarization state.

15. A method of illuminating a sample, wherein
directing radiation from an illumination source toward a first surface of a polarization beam splitter (PBS);
polarizing the radiation to a first polarization state;
transferring the radiation into a chamber via a collimating optic toward a reflector, disposed in the chamber, the reflector comprising a waveplate configured to change a polarization of the radiation to a second polarization state different from the first polarization state;
reflecting the radiation on the reflector via the waveplate toward the collimating optic;
receiving a portion of the radiation polarized at the second polarization state at a detector; and
generating bright field image data using a detector oriented to receive the portion of the radiation via the PBS.

16. The method of claim 15, wherein:
a first optical path between the illumination source and the reflector defines a source distance;
a second optical path between the reflector and the detector defines a partial focal distance; and
the source distance is about equal to or greater than the partial focal distance.

17. The method of claim 15, further comprising rotating a sample disposed in the chamber between the reflector and the collimating optic, wherein generating the image data comprises generating a plurality of bright field images of the sample and a plurality of rotation angles.

18. The method of claim 15, further comprising generating profile data describing a surface of a sample using the bright field image data, the sample being disposed in the chamber and coupled with a sample stage.

19. The method of claim 18, further comprising generating imaging instructions to image at least a portion of the surface of the sample based at least in part on the profile data.

20. The method of claim 19, wherein the imaging instructions comprise motion instructions describing a motion of the sample stage.
